(19) United States
(12) Patent Application Publication
(10) Pub. No.: US 2002/0053720 A1
(43) Pub. Date: May 9, 2002

(54) Substrate for an electronic circuit, and an electronic module using such a substrate

(75) Inventors: Benoit Boursat, Bizanos (FR); Emmanuel Dutarde, Aureilhan (FR); Luc Meysenc, Semeac (FR); Jose Saiz, Cenon (FR); Pierre Solomalala, Aureilhan (FR)

Correspondence Address: SUGHRUE MION ZINN MACPEAK & SEAS, PLLC, 2100 Pennsylvania Avenue, NW, Washington, DC, 20037-3213, US

(73) Assignee: ALSTOM

(21) Appl. No.: 09/951,391

(22) Filed: Sep. 14, 2001

(30) Foreign Application Priority Data
Sep. 15, 2000 (FR) 00 11 802.

(51) Int. Cl. H01L 29/82

(52) U.S. Cl. 257/640; 257/418; 257/669; 257/760

(57) ABSTRACT

A substrate for an electronic circuit, the substrate comprising a wafer of silicon Si having a top face covered in an electrically insulating layer of silicon nitride SiN, said electrically insulating layer of silicon nitride supporting one or more conductive tracks obtained by metallizing the top face of said electrically insulating layer for the purpose of enabling one or more electronic components to be connected.

The invention relates to a substrate for an electronic circuit, in particular a power electronic circuit, and more particularly it relates to a substrate for withstanding a potential difference between conductive tracks disposed on the top face of the substrate and a cooling system touching the bottom face of the substrate, while still providing good heat exchange. The substrate of the invention is for supporting passive components, and power semiconductor components, and in particular insulated gate bipolar transistors (IGBTs), as used in circuits for distributing power in railways and in mains distribution where voltage values are particularly high.

### BACKGROUND OF THE INVENTION

In the prior art, it is known to have substrates for electronic power circuits that comprise an electrically insulating wafer of aluminum nitride AlN covered on its top and bottom faces in copper metallization that is about 300 micrometers (μm) thick by means of a technique known as direct bonding copper (DBC). To improve cooling, a radiator is usually brought into contact with the bottom layer of copper so as to dump the heat given off by the power components.

Such a substrate has an electrically insulating wafer of aluminum nitride AlN that possesses very good thermal conductivity but that nevertheless presents the drawback of requiring bonding layers to be formed by the DBC method at the interface between the AlN wafer and the copper metallization, which bonding layers constitute a thermal barrier that considerably reduces the heat transmission ability of the substrate. In addition, the large difference between the thermal expansion coefficients of aluminum nitride AlN (4.2 μm/m) and copper (16.4 μm/m) and the large variation in temperature, in the range 70° C. to 110° C. depending on the operation of the power components, give rise to mechanical stresses within the substrate, and above all at the interfaces which can, in the long run, lead to the substrate breaking.

### OBJECT AND SUMMARY OF THE INVENTION

The object of the present invention is thus to propose a novel type of substrate for receiving electronic components, and in particular power semiconductors which enable the above-mentioned drawbacks of the prior art to be mitigated while being simple and low cost to implement.

To this end, the invention provides a substrate for an electronic circuit, the substrate comprising a wafer of silicon Si having a top face covered in an electrically insulating layer of silicon nitride SiN, said electrically insulating layer of silicon nitride supporting one or more conductive tracks obtained by metallizing the top face of said electrically insulating layer for the purpose of enabling one or more electronic components to be connected.

In particular embodiments, the substrate for an electronic circuit can comprise one or more of the following characteristics taken in isolation or in any technically feasible combination:

a layer of silicon oxide SiO₂ is interposed between said silicon wafer and said insulating layer, said layer of SiO₂ possessing small thickness and serving as a bonding layer for the deposit of said insulating layer of silicon nitride of greater thickness;

at least one of said electronic components is a power semiconductor component;

said electrically insulating layer of silicon nitride possesses a multilayer structure built up of different types of silicon nitride comprising in succession layers under tension and layers under compression such that the stresses on the silicon wafer compensate;

the various layers of silicon nitride in the electrically insulating layer are obtained essentially by plasma-enhanced chemical vapor deposition, PECVD;

at least one layer of silicon nitride making up the electrically insulating layer is obtained by low pressure chemical vapor deposition, LPCVD;

the metallization for the conductive track is obtained by growing copper electrolytically;

the bottom face of the silicon wafer has fluting forming channels over which a cooling fluid flows; and

the bottom face of the silicon wafer is covered in a layer of silicon oxide and in an electrically insulating layer of silicon nitride.

The invention also provides an electronic module comprising at least one electronic component mounted on a substrate in accordance with the characteristics described above.

### BRIEF DESCRIPTION OF THE DRAWING

The objects, aspects, and advantages of the present invention will be better understood on reading the following description of various embodiments, given as non-limiting examples and with reference to the accompanying drawing, in which:

FIG. 1 is a diagrammatic section view of a prior art substrate;

FIG. 2 is a diagrammatic section view of a substrate constituting a first embodiment of the invention;

FIG. 3 is a diagrammatic section view of a power module using the FIG. 2 substrate; and

FIG. 4 is a diagrammatic section view of a second embodiment of the substrate of the invention.

### MORE DETAILED DESCRIPTION

To make the drawing easier to read, only those elements which are necessary for understanding the invention have been shown. The same elements are given the same references from one figure to another.

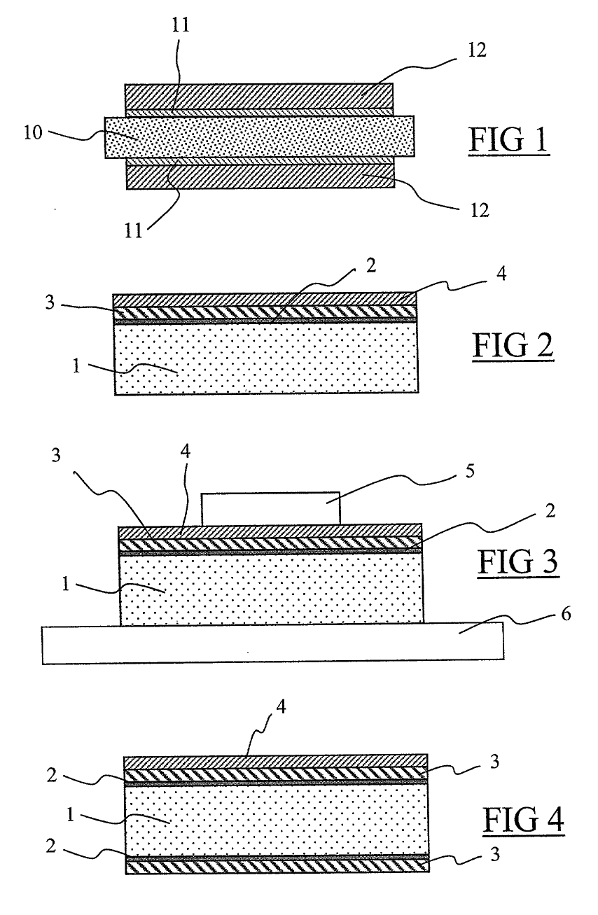

FIG. 1 shows a prior art substrate comprising an electrically insulating wafer 10 of aluminum nitride AlN having a thickness of 635 μm covered on its bottom and top faces in respective sheets of copper 12. The sheets of copper 12 are about 300 μm thick and they are deposited by a direct bonding copper (DBC) method which consists in bringing the copper sheets 12 onto the AlN wafer 10 and in raising the assembly to very high temperatures so as to create a bonding layer 11 having a thickness of about 5 μm at the interface between the copper sheets 12 and the wafer 10 of aluminum nitride. In such a substrate, the top copper sheet 12 is used to make conductive tracks for receiving power components, and the bottom copper sheet 12 is used to compensate the stresses generated by differential expansion between the top copper sheet 12 and the AlN wafer 10 so as to avoid deforming the substrate.

As can be seen in the following table, such a substrate possesses a total heat exchange coefficient between its two outer faces of about 10⁻⁵ watts per square meter and per Kelvin (W/m²K) in which the bonding layer 11 amounts for 50% of the total heat exchange coefficient of the substrate.

| | | Thermal | Heat exchange |
|---|---|---|---|
| | Thickness | conductivity | coefficient = |
| | e (μm) | λ (W/m · K) | e/λ (W/m² · K) |
| Copper layers | 2 × 300 | 385 | 1.5 × 10⁻⁶ |
| Bonding layers | ˜5 | ˜1 | 5 × 10⁻⁶ |
| AlN | 635 | 180 | 3.5 × 10⁻⁶ |
| Total | | | × 10⁻⁵ |

FIG. 2 shows a substrate constituting a particular embodiment of the invention. As shown in this figure, the substrate comprises a 500 μm thick wafer 1 of silicon Si whose top face is covered in a layer 2 of silicon oxide SiO₂. This layer of silicon oxide SiO₂ is about 0.05 μm thick and is obtained by oxidizing the top face of the silicon wafer 1 by a growth method in an oven with injection of oxygen or water vapor. Such a method leads to all of the faces of the silicon wafer 1 being oxidized, with the layer of oxide on the bottom face of the wafer 1 being eliminated by etching. Naturally, a method that enables a single layer of silicon oxide to be obtained directly on one face only could also be used.

The layer 2 of silicon oxide SiO₂ on the top face of the silicon wafer 1 is used as a binding surface onto which an electrically insulating layer 3 of silicon nitride SiN is deposited. This electrically insulating layer 3 is constituted by a multilayer structure of various different silicon nitrides advantageously deposited using a plasma-enhanced chemical vapor deposition technique (PECVD).

The various layers of silicon nitride are deposited in succession with the parameters of the plasma torch being modified between layers, and in particular the frequency of the plasma, so as to obtain alternating layers under tension that generate stresses tending to make the substrate concave and layers under compression generating stresses that tend to make the substrate convex. The multilayer structure built up in this way serves to obtain an electrically insulating layer of silicon nitride that is about 10 μm thick and that is suitable for insulating voltages in the range 10 kilivolts (kV) to 20 kV, without generating excessive stresses on the silicon wafer 1 so as to avoid breaking it. Naturally, the thickness of the insulating layer 3 of silicon nitride increases with increasing voltage to which the substrate is to be subjected.

In a variant embodiment, the multilayer structure could also include a layer of pure silicon nitride Ni₃N₄ obtained by a low pressure chemical vapor deposition method (LPCVD). Such a layer presents the advantage of having a better breakdown voltage than silicon nitride obtained by the PECVD method. The resulting layer of pure silicon nitride is a layer under tension that generates very high stresses tending to make the substrate concave, so it needs to be covered in a layer of silicon nitride obtained by the PECVD method that is under compression so as to compensate the stresses acting on the silicon wafer 1 and avoiding causing it to break.

The top face of the electrically insulating layer 3 of silicon nitride is covered in a layer of copper 4 having a thickness of about 150 μm, which layer is grown electrolytically. The copper layer 4 is used to make one or more conductive tracks for receiving a power component 5 such as an IGBT component, as shown in FIG. 3.

The bottom face of the substrate is brought into contact with a cooling radiator 6 for dumping the heat given off by the IGBT component 5 as transmitted through the substrate. In a variant embodiment (not shown), the cooling radiator can be integrated directly with the substrate by making fluting on the bottom face of the silicon wafer 1 so as to form channels in which a cooling fluid flows.

As shown in the following table, such a substrate possesses a total heat exchange coefficient between its two faces of about 4.1×10⁻⁶ W/m².K.

| | | Thermal | Heat exchange |
|---|---|---|---|
| | Thickness | conductivity | coefficient = |
| | e (μm) | λ (W/m · K) | e/λ (W/m² · K) |
| Copper layers | 150 | 335 | 0.4 × 10⁻⁶ |
| SiN | 150 | 25 | 0.4 × 10⁻⁶ |
| SiO₂ | 0.05 | 1.38 | 3.6 × 10⁻⁸ |
| Si | 500 | 150 | 3.3 × 10⁻⁶ |
| Total | | | 4.1 × 10⁻⁶ |

Such a substrate presents the advantage of having structure that is very uniform with a bonding layer of SiO₂ that is very thin and that possesses thermal resistance that is very low and not penalizing for the overall performance of the substrate. In addition, this layer of silicon oxide SiO₂ contributes to absorbing a fraction of the stresses generated by the insulating layer of silicon nitride, and thus for given stress on the silicon wafer, makes it possible to increase the thickness of the insulating layer of silicon nitride.

The substrate of the invention also presents the advantage of possessing thermal expansion coefficients for the silicon wafer (TEC=2.5 μm/m) and for the electrically insulating layer of silicon nitride (TEC=3 μm/m) that are very close to that of the power components mounted on the substrate, thus having the consequence of considerably reducing the thermomechanical stresses and thus of increasing the reliability of power modules using such a substrate. This good match between the thermal expansion coefficients of the various layers of the substrate with the coefficients of power chips is particularly advantageous for accommodating the use of novel silicon carbide (SiC) power components having an operating temperature of about 150° C., while retaining acceptable thermomechanical reliability in spite of the increase in thermomechanical stresses compared with power components that normally operate at 110° C.

FIG. 4 shows a second embodiment of the substrate of the invention in which the silicon wafer 1 is covered on both faces in a layer 2 of silicon oxide SiO₂ and in an electrically insulating layer 3 built up from a multilayer structure of silicon nitride SiN. The layers 2 and 3 on both faces are obtained by methods similar to those described for the preceding embodiment.

By retaining the deposit on both faces of the silicon wafer, this variant embodiment presents the advantage of simplifying manufacture of the substrate, since both the method of depositing the layer of silicon oxide by growth in an oven and the method of depositing the silicon nitride (SiN) layer by low pressure chemical vapor deposition (LPCVD) naturally lead to deposits being made on both faces of the silicon wafer. This simplification in the method of manufacturing the substrate by retaining the deposit on both faces of the silicon wafer does not harm overall thermal conductivity of the substrate excessively because of the good thermal conductivity of the silicon oxide and silicon nitride layers.

Naturally, the invention is not limited in any way to the embodiments described and shown, and given purely by way of example.

Thus, the substrate of the invention is advantageously applied to the field of electronic power circuits, but can also be used to support passive electronic components in the field of conventional electronic circuits.

1/ A substrate for an electronic circuit, the substrate comprising a wafer of silicon Si having a top face covered in an electrically insulating layer of silicon nitride SiN, said electrically insulating layer of silicon nitride supporting one or more conductive tracks obtained by metallizing the top face of said electrically insulating layer for the purpose of enabling one or more electronic components to be connected, wherein said electrically insulating layer of silicon nitride possesses a multilayer structure built up of different types of silicon nitride comprising in succession layers under tension and layers under compression such that the stresses on the silicon wafer compensate.

2/ An electronic circuit substrate according to claim 1, wherein a layer of silicon oxide SiO₂ is interposed between said silicon wafer and said insulating layer, said layer of SiO₂ possessing small thickness and serving as a bonding layer for the deposit of said insulating layer of silicon nitride of greater thickness.

3/ An electronic circuit substrate according to claim 1, wherein at least one of said electronic components is a power semiconductor component.

4/ A power electronic circuit substrate according to claim 1, wherein the various layers of silicon nitride in the electrically insulating layer are obtained essentially by plasma-enhanced chemical vapor deposition, PECVD.

5/ A power electronic circuit substrate according to claim 1, wherein at least one layer of silicon nitride making up the electrically insulating layer is obtained by low pressure chemical vapor deposition, LPCVD.

6/ A power electronic circuit substrate according to claim 1, wherein the metallization for the conductive track is obtained by growing copper electrolytically.

7/ A power electronic circuit substrate according to claim 1, wherein the bottom face of the silicon wafer has fluting forming channels over which a cooling fluid flows.

8/ A power electronic circuit substrate according to claim 1, wherein the bottom face of the silicon wafer is covered in a layer of silicon oxide and in an electrically insulating layer of silicon nitride.

9/ An electronic module, including at least one electronic component mounted on a substrate according to claim 1.
